(19) United States
(12) Patent Application Publication
(10) Pub. No.: US 2017/0148878 A1
(43) Pub. Date: May 25, 2017

(54) BI-MODE INSULATED GATE TRANSISTOR

(71) Applicant: JIANGSU ZHONGKE JUNSHINE TECHNOLOGY CO. LTD., Wuxi (CN)

(72) Inventors: Wenliang ZHANG, Wuxi (CN); Yangjun ZHU, Wuxi (CN); Junyu GAO, Wuxi (CN)

(73) Assignee: JIANGSU ZHONGKE JUNSHINE TECHNOLOGY CO. LTD., Wuxi (CN)

(21) Appl. No.: 15/321,688

(22) PCT Filed: Aug. 11, 2014
(86) PCT No.: PCT/CN2014/084086

§ 371 Date: Dec. 22, 2016

(30) Foreign Application Priority Data
Jun. 24, 2014 (CN) 201410287757.3

(51) Int. Cl. H01L 29/10; H01L 29/08; H01L 29/739

(52) U.S. Cl. CPC H01L 29/1083; H01L 29/7395; H01L 29/1095; H01L 29/0821

(57) ABSTRACT

The present invention discloses a bi-mode insulated gate transistor, belonging to the technical filed of IGBTs. The bi-mode insulated gate transistor includes a reverse conducting region and a pilot region, wherein the reverse conducting region and the pilot region each include P+ collector regions, a drift region and a MOS cell region, the drift regions are disposed over the P+ collector regions, and the MOS cell regions are disposed over the drift regions; the reverse conducting region further includes N+ collector regions, and the N+ collector regions and the P+ collector regions are distributed alternatively; the pilot region further includes a separation region or a low-doped region, the separation region isolates the P+ collector regions of the pilot region from the P+ collector regions and the N+ collector regions of the reverse conducting region, and the low doped region is disposed over the P+ collector regions of the pilot region. In the present invention, the resistance of an electron current channel over the pilot region or a built-in potential of a PN junction of the collector of the pilot region is increased when a device works in a VDMOS mode, in order to reduce the size of the pilot region of the bi-mode insulated gate transistor, so that the uniformity of current intensity inside the device in work is increased, and the overall reliability of the device is further improved.

### FIELD OF THE INVENTION

The present invention relates to the technical filed of IGBTs, and in particular to a bi-mode insulated gate transistor.

### BACKGROUND OF THE INVENTION

As for an RC-IGBT, N+ doped regions (N+ collector regions) are introduced to a collector region on the back of a traditional IGBT so as to add a reverse current channel to a device. The RC-IGBT has advantages in cost and performance and can replace the traditional IGBT in some fields. The biggest problem of the RC-IGBT is that snap-back (hereinafter referred to as “snap-back”) of voltage occurring at the time of conduction severely limits the application of the device. In order to suppress the snap-back phenomenon, with respect to the RC-IGBT, it generally needs to ensure that the space between adjacent N+ collector regions is big enough, however, non-uniform distribution of current inside a chip is accordingly caused, thus affecting the reliability of the device. To this end, a BIGT (Bi-mode Insulated Gate Transistor) structure is proposed to integrate the RC-IGBT and the traditional IGBT structure into a same chip. According to the working principle of the device, the traditional IGBT region inside the chip is called a pilot region (Pilot IGBT region). The pilot region mainly functions to guide a device to enter an IGBT mode at the initial stage of conduction so as to avoid snap-back, which allows more free design of the RC-IGBT, and thus the space between adjacent N+ collector regions can be reduced for improving the uniformity of current.

The pilot region is introduced to allow more free deign of the RC-IGBT region and no need of considering the issue of suppressing snap-back during design of the space between the N+ collector regions. This increases the degree of freedom of design, and is beneficial to optimizing the overall performance of the RC-IGBT more sufficiently. Therefore, in the RC-IGBT region of the chip of the bi-mode insulated gate transistor, the space between the N+ collector regions can be properly reduced to improve the current uniformity inside the chip. The bi-mode insulated gate transistor, however, does not thoroughly improve the current uniformity inside the chip, and in fact, only the current distribution of the RC-IGBT region is relatively uniform, while the current uniformity of the pilot region and the N+ collator regions nearby is still low. For example, when the bi-mode insulated gate transistor works in an IGBT mode, the current density of the intermediate region of the pilot region is much bigger than that of the edge of the pilot region and that of a reverse conducting region. When the bi-mode insulated gate transistor works in a diode mode, the current density of the N+ collector regions adjacent to the pilot region is much bigger than that of other N+ collector regions. Thus, the device structure of the bi-mode insulated gate transistor still has reliability risk.

The bi-mode insulated gate transistor can allow more free design of the RC-IGBT, thus improving the current uniformity inside the chip to some degree, however, the problem of serious current concentration may still occur near the pilot region of the bi-mode insulated gate transistor to result in poor reliability of the chip, which is mainly showed in the follow aspects:

First, temperature differences of different regions inside the chip are large, and inside the chip, poor power circulation performance of a device is caused by introduction of large stress due to temperature gradient.

Second, as the current is concentrated in regions with some characteristics, when the device bears current overshoot, some weak regions of the chip will be burned down, so that the capability of the device of resisting current overshoot is poor.

Third, as current may be concentrated in regions with some characteristics, the capability of the device of resisting short circuit is poor.

The above three aspects all will result in poor reliability of the device, which is unfavorable for safe work of the device for a long time.

### SUMMARY OF THE INVENTION

A technical problem to be solved by the present invention is to provide a bi-mode insulated gate transistor, so as to solve the technical problem that the size of the pilot region of the bi-mode insulated gate transistor in the prior art is too large, resulting in serious current concentration of the pilot region and regions nearby.

In order to solve the above technical problem, the present invention provides a bi-mode insulated gate transistor, including a reverse conducting region and a pilot region;
the reverse conducting region and the pilot region each include P+ collector regions, a drift region and a MOS cell region, wherein the drift regions are disposed over the P+ collector regions, and the MOS cell regions are disposed over the drift regions;
the reverse conducting region further includes N+ collector regions, and the N+ collector regions and the P+ collector regions are alternatively distributed;
wherein the guide region further includes a separation region or a low doped region, the separation region isolates the P+ collector regions of the pilot region from the P+ collector regions and the N+ collector regions of the reverse conducting region, and the low doped region is disposed over the P+ collector regions of the pilot region. Further, the reverse conducting region and the pilot region each can further include an N+ buffer layer, the N+ buffer layer of the reverse conducting region is between the P+ collector regions or the N+ collector regions of the reverse conducting region and the drift region of the reverse conducting region, the N+ buffer layer of the pilot region is between the P+ collector regions of the pilot region and the drift region of the pilot region, and the separation region of the pilot region isolates the N+ buffer layer of the reverse conducting region and the N+ buffer layer of the pilot region. Further, an insulator region is below the separation region, the insulator region is located between a silicon substrate and a collector metal layer, and the width of the insulator region is adjusted to realize potential isolation of the N+ buffer layer of the pilot region and collector metal.

Further, the separation region is a groove filled with an insulator.

Further, the doped concentration of the N+ buffer layer of the pilot region is smaller than that of the N+ buffer layer of the reverse conducting region.

Further, the doped concentration of the low doped region is smaller than those of the N+ buffer layer of the pilot region and the P+ collector regions of the pilot region.

As for the bi-mode insulated gate transistor provided by the present invention, the separation region or the insulator groove is arranged to increase the resistance of an electron current channel of a device in a VDMOS mode, and reduce the size of the pilot region of the bi-mode insulated gate transistor. The current inside the chip is distributed more uniformly when the device is in work, so that the overall reliability of the device is improved. In addition, the low doped region is arranged to reduce the turn-on voltage of a collector PN of the pilot region, so as to reduce the size of the pilot region of the bi-mode insulated gate transistor. The current inside the chip is distributed more uniformly when the device is in work, so that the overall reliability of the device is improved.

### BRIEF DESCRIPTION OF THE DRAWINGS

FIG. 1 is a bi-mode insulated gate transistor provided by embodiment 1 of the present invention, wherein over one side of an insulator close to a reverse conducting region is a P+ collector region;

FIG. 2 is a bi-mode insulated gate transistor provided by embodiment 1 of the present invention, wherein over one side of an insulator close to a reverse conducting region is an N+ collector region;

FIG. 3 is a backside layout of a bi-mode insulated gate transistor with an N+ collector region of a strip shape provided by embodiment 1 of the present invention;

FIG. 4 is a backside layout of a bi-mode insulated gate transistor with an N+ collector region of a round shape provided by embodiment 1 of the present invention;

FIG. 5 is a bi-mode insulated gate transistor provided by embodiment 2 of the present invention, wherein over one side of a groove an insulator close to a reverse conducting region is a P+ collector region and a separation region is a groove;

FIG. 6 is a bi-mode insulated gate transistor provided by embodiment 2 of the present invention, wherein on one side of a groove of an insulator close to a reverse conducting region is an N+ collector region and a separation region is a groove;

FIG. 7 is a bi-mode insulated gate transistor provided by embodiment 3 of the present invention, wherein no N+ buffer layer is provided, and on one side of a groove of an insulator close to a reverse conducting region is a P+ collector region;

FIG. 8 is a bi-mode insulated gate transistor provided by embodiment 3 of the present invention, wherein no N+ buffer layer is provided, and on one side of a groove of an insulator close to a reverse conducting region is an N+ collector region;

FIG. 9 is a bi-mode insulated gate transistor provided by embodiment 4 of the present invention, wherein the doped concentration of the buffer layer of a pilot region is smaller than that of the buffer layer of a reverse conducting region and the buffer layer with low concentration partially covers a P+ collector region;

FIG. 10 is a bi-mode insulated gate transistor provided by embodiment 4 of the present invention, wherein the doped concentration of the buffer layer of a pilot region is smaller than that of the buffer layer of a reverse conducting region and the buffer layer with low concentration wholly covers a P+ collector region;

FIG. 11 is a bi-mode insulated gate transistor provided by embodiment 5 of the present invention, wherein a pilot region includes a low doped region wholly covering a P+ collector region.

FIG. 12 is a bi-mode insulated gate transistor provided by embodiment 5 of the present invention, wherein a pilot region includes a low doped region partially covering a P+ collector region.

### DETAILED DESCRIPTION OF THE EMBODIMENTS

Referring to FIG. 1, embodiments of the present invention provide a bi-mode insulated gate transistor, including a reverse conducting region and a pilot region;
the reverse conducting region and the pilot region each include P+ collector regions, a drift region and a MOS cell region, wherein the drift regions are disposed over the P+ collector regions, and the MOS cell regions are disposed over the drift regions;
the reverse conducting region further includes N+ collector regions, and the N+ collector regions and the P+ collector regions are alternatively distributed;
the guide region further includes a separation region or a low doped region, the separation region isolates the P+ collector regions of the pilot region from the P+ collector regions and the N+ collector regions of the reverse conducting region, and the low doped region is disposed over the P+ collector regions of the pilot region.
As for the bi-mode insulated gate transistor provided by the present invention, the separation region or the insulator groove is arranged to increase the resistance of an electron current channel of a device in a VDMOS mode, and reduce the size of the pilot region of the bi-mode insulated gate transistor. The current inside the chip is distributed more uniformly when the device is in work, so that the overall reliability of the device is improved. In addition, the low doped region is arranged to reduce the turn-on voltage of a collector PN of the pilot region, so as to reduce the size of the pilot region of the bi-mode insulated gate transistor. The current inside the chip is distributed more uniformly when the device is in work, so that the overall reliability of the device is improved.

### Embodiment 1

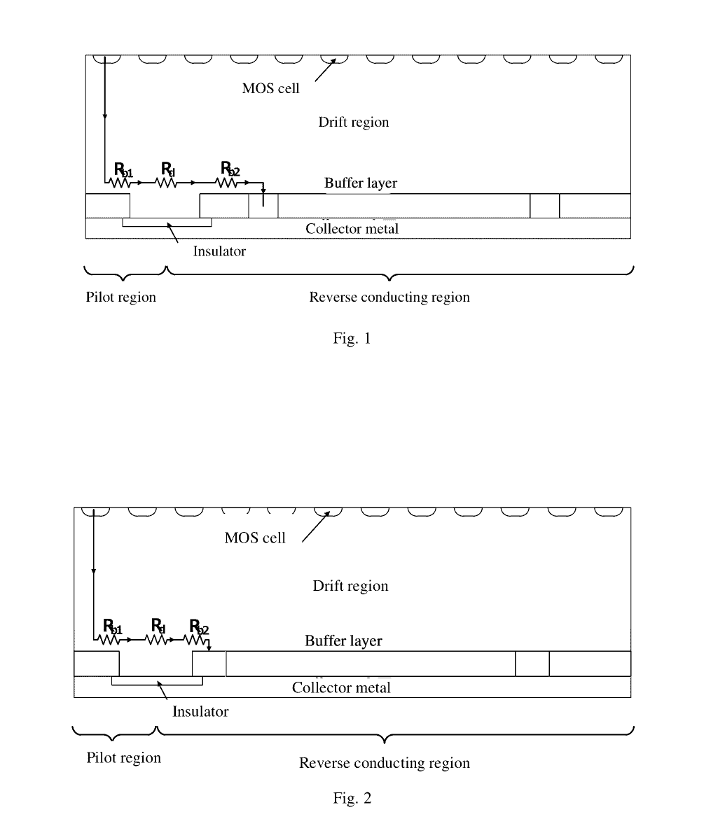

Referring to FIGS. 1, 2 3 and 4, the pilot region includes a separation region in the embodiment, the basic conception of which is that the N+ buffer layer of the pilot region is separated from the N+ buffer layer of the reverse conducting region, that is to say, the two buffer layers are isolated from each other, as shown in FIGS. 1 and 2. The separation region is a doped semiconductor substrate to which no buffer layer is introduced, and generally, the doped concentration of the separation region is generally the same as that of an N− drift region. Of course, a small amount of impurities may be properly introduced or the separation region is manufactured into a semiconductor structure of which the resistivity is large than that of the N− drift region.

In order to ensure the voltage withstanding performance of a device, an insulator region of a certain size is manufactured under the separation region, and is located between the semiconductor substrate and a collector metal layer. Potential isolation of the N+ buffer layer and a collector metal should be ensured through the width of the insulator, the insulator region has the function of preventing punch-through breakdown caused by contact of a boundary of a depletion region and the collector metal when the device withstands voltage.

In the embodiment, over one side of the insulator close to the reverse conducting region may be arranged a segment of a P+ collector region (as in FIG. 1), or may be directly arranged an N+ collector region (as in FIG. 2).

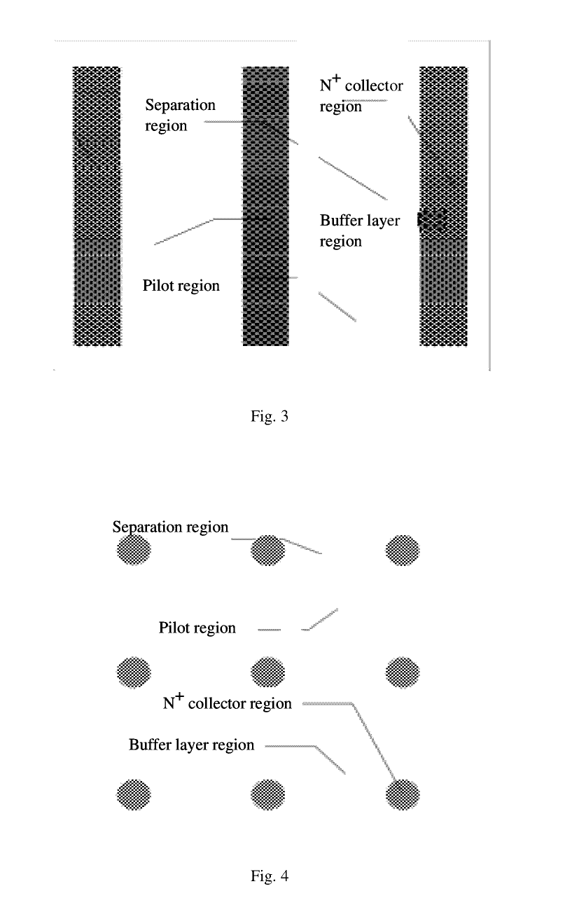

FIGS. 3 and 4 are used as examples for a backside layout. Isolation of the buffer layer of the pilot region may reduce the space between the N+ collector regions on two sides of or surrounding the pilot region to a level equivalent to the space between the N+ collector regions of the reverse conducting region. Thus, the N+ collector regions can be uniformly and regularly distributed within a whole chip, thus greatly improving the current uniformity. In this way, when the device is in a VDMOS mode, electron current over the pilot region must flow through the buffer layer (with the distribution resistance of Rb1) of the pilot region, a low doped region (with the distribution resistance of Rd) of the separation region, and a buffer layer (with the distribution resistance of Rb2) of the reverse conducting region. The low doped region is between the buffer layers, so Rd>>Rb1+Rb2. The introduction of Rd enables the pilot region to be sufficient to suppress snap-back of the device without widening the P+ collector regions, so that the space between the N+ collector regions on two sides of or surrounding the pilot region is reduced. The size of Rd can be controlled by adjusting the width and doped concentration of the low doped region at discontinuity of the buffer layer, so that the width of the pilot region can be reduced to a level equivalent to the width of the P+ collector region of the reverse conducting region, so that the problem of current uniformity is greatly improved. Generally, the larger the width of the low doped region between the buffer layers is, the lower the doped concentration is, the larger Rd is, and the more the reduction of the width of the pilot region may be. However, it is not better that the resistance of Rd is larger, as long as it can ensure that snap-back of the device does not occur.

### Embodiment 2

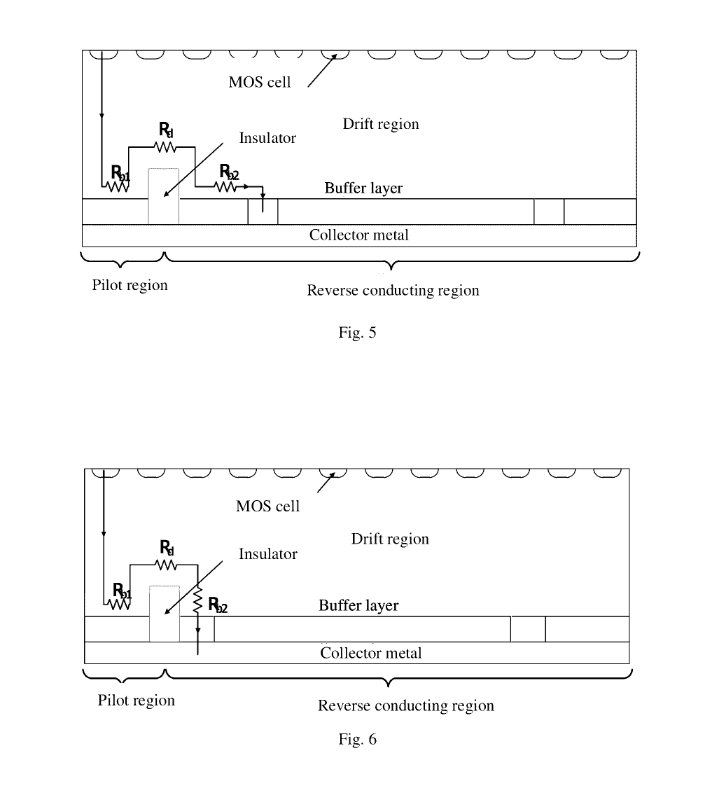

The bi-mode insulated gate transistor provided by the embodiment is similar to that in embodiment 1 in structure. The two differ in that the separation region of embodiment 2 is a groove filled with an insulator, and the N+ buffer layer and the collector region are separated by the groove filled with the insulator (as shown in FIGS. 5 and 6). The buffer layer at the left side of the groove as shown in the figure is the buffer layer of the pilot region, and the buffer layer at the right side of the groove is the buffer layer of the reverse conducting region.

In the embodiment, over one side of the insulator close to the reverse conducting region may be arranged a segment of a P+ collector region (as in FIG. 5), or may be directly arranged an N+ collector region (as in FIG. 6).

When the device is in a VDMOS mode, electron current over the pilot region must flow through the buffer layer (with the distribution resistance of Rb1) of the pilot region, low doped regions (with the distribution resistance of Rd) on two sides of and above the groove, and a buffer layer (with the distribution resistance of Rb2) of the reverse conducting region. The low doped regions are on two ides of and above the groove, so Rd>>Rb1+Rb2. The introduction of Rd enables the pilot region to be sufficient to suppress snap-back of the device without widening the P+ collector region, so that the space between the N+ collector regions on two sides of or surrounding the pilot region is reduced. The size of Rd can be controlled by adjusting the width and depth of the groove, so that the width of the pilot region can be reduced to a level equivalent to the width of the P+ collector region of the reverse conducting region, so that the problem of current uniformity is greatly improved. Generally, the larger the width and depth of the groove are, the larger Rd is, and the more the reduction of the width of the pilot region may be. However, it is not better that the resistance of Rd is larger, as long as it is ensured that snap-back of the device does not occur.

### Embodiment 3

In fact, not only can the bi-mode insulated gate transistor of an FS structure adopt this solution, but also the current uniformity of the bi-mode insulated gate transistor of an NPT structure can be improved. The structure of the reverse conducting region proposed in embodiment 3 is similar to that of embodiment 2. The two differ in that the structure in embodiment 3 does not include the N+ buffer layer structure.

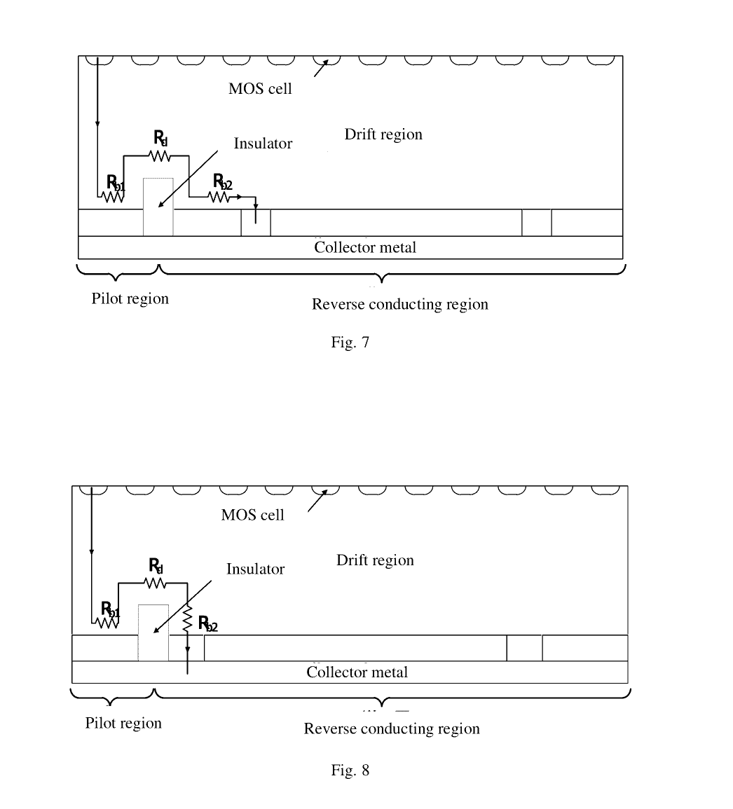

In the embodiment, on one side of the insulator close to the reverse conducting region may be arranged a segment of a P+ collector region (as in FIG. 7), or may be directly arranged an N+ collector region (as in FIG. 8).

When the device is in a VDMOS mode, electron current over the pilot region must flow through the drift region (with the distribution resistance of Rd1) of the pilot region, low doped regions (with the distribution resistance of Rd) on two sides of and above the groove, and the drift region (with the distribution resistance of Rd2) over the N+ collector region of the reverse conducting region. The introduction of Rd enables the pilot region to be sufficient to suppress snap-back of the device without widening the P+ collector region, so that the space between the N+ collector regions on two sides of or surrounding the pilot region is reduced. The size of Rd can be controlled by adjusting the width and depth of the groove, so that the width of the pilot region can be reduced to a level equivalent to the width of the P+ collector region of the reverse conducting region, so that the problem of current uniformity is greatly improved. Generally, the larger the width and depth of the groove are, the larger Rd is, and the more the reduction of the width of the pilot region may be. However, it is not better that the resistance of Rd is larger, as long as it is ensured that snap-back of the device does not occur.

### Embodiment 4

In the embodiment, the doped concentration of the N+ buffer layer of the pilot region is properly reduced on the premise of ensuring enough voltage withstanding of the device. That is to say, the doped concentration of the buffer layer of the pilot region is smaller than that of the buffer layer of the reverse conducting region.

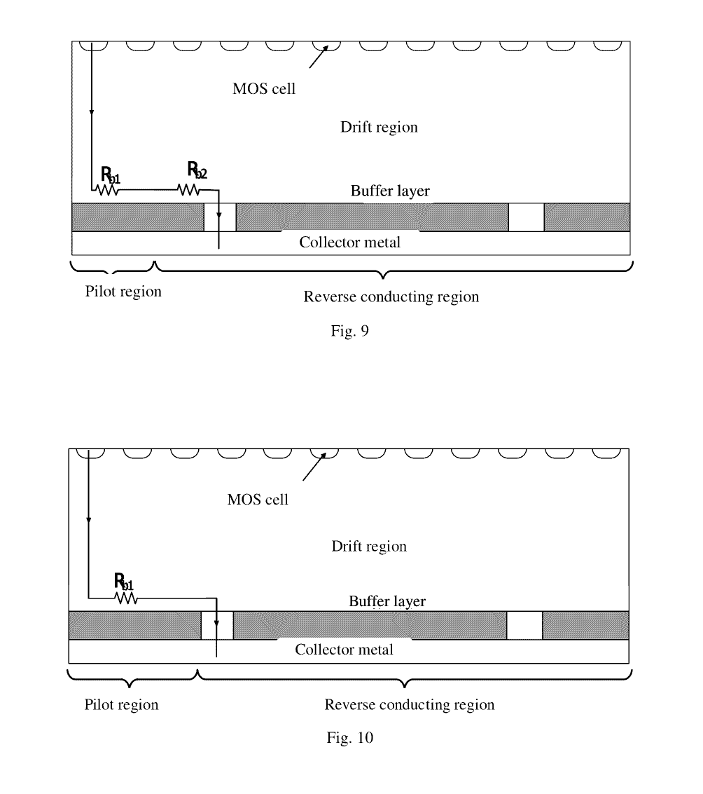

In the embodiment, the low doped buffer layer over the pilot region can partially cover the P+ collector region (as in FIG. 9), or wholly cover the P+ collector region (as in FIG. 10), or even wholly or partially cover adjacent N+ collector regions.

When the device is in a VDMOS mode, electron current over the pilot region must flow through the low doped buffer layer (with the distribution resistance of Rb1) of the pilot region, and a high doped buffer layer (with the distribution resistance of Rb2) of the pilot region. Due to the introduction of the low doped buffer layer, Rb1+Rb2 reaches a high level. In addition, due to the introduction of the low doped buffer layer, the turn-on voltage of the PN junction formed by the P+ collector region and the N+ buffer layer is reduced. The two factors above enable the pilot region to be sufficient to suppress snap-back of the device without widening the P+ collector region, so that the space between the N+ collector regions on two sides of or surrounding the pilot region is reduced. The size of Rb1 can be controlled by adjusting the length of the low doped buffer layer, so that the width of the pilot region can be reduced to a level equivalent to the width of the P+ collector region of the reverse conducting region, so that the problem of current uniformity is greatly improved. Generally, the larger the length of the low doped buffer layer is, the larger Rb1 is, and the more the reduction of the width of the pilot region may be. However, it is not better that the resistance of Rb1 is larger, as long as it is ensured that snap-back of the device does not occur.

### Embodiment 5

In the embodiment, the doped concentration of the low doped region is smaller than those of the N+ buffer layer of the pilot region and the P+ collector regions of the pilot region.

The low doped region may be P-type or N-type, or may also include a P region and an N region. In the case of including both the P region and the N region, it needs to ensure the P-type low doped region is located over the P+ collector region, and the N-type low doped region is located between the P-type low-doped region and the N+ buffer layer.

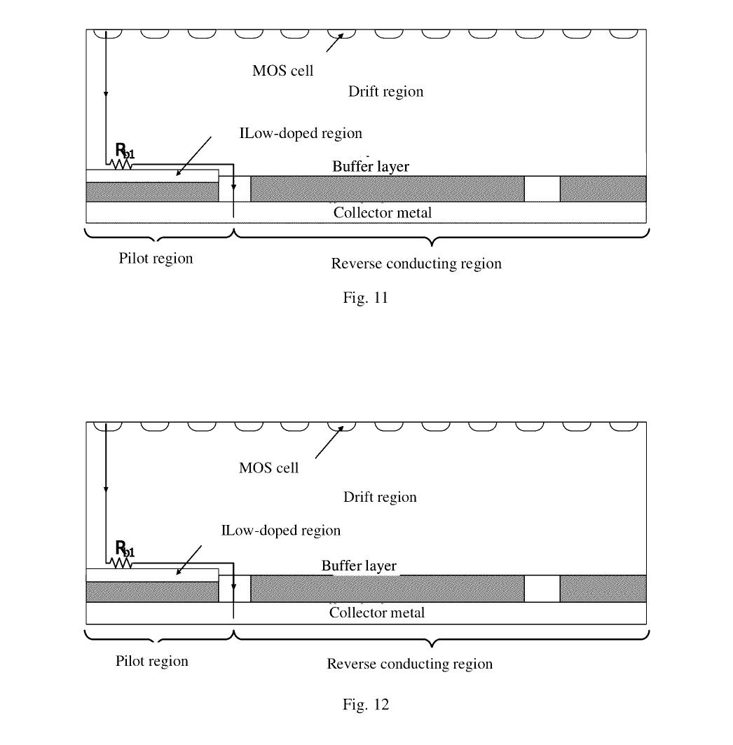

In the embodiment, the low doped region of the pilot region can partially cover the P+ collector region (as in FIG. 11), or wholly cover the P+ collector region (as in FIG. 12), or even wholly or partially cover adjacent N+ collector regions.

The low doped region is introduced between the N+ buffer layer of the pilot region and the P+ collector region of the device, so that a low doped semiconductor is located on one or two sides of the PN junction of the collector, in order to greatly reduce the turn-on voltage of the PN junction. Therefore, the pilot region is sufficient to suppress snap-back of the device without widening the P+ collector region, so that the space between the N+ collector regions on two sides of or surrounding the pilot region is reduced. The amplitude of turn-on voltage of the PN junction can be controlled by adjusting the concentration of the low doped region, so that the width of the pilot region can be reduced to a level equivalent to the width of the P+ collector region of the reverse conducting region, so that the problem of current uniformity is greatly improved. Generally, the lower the doped concentration of the low doped region is, the smaller the voltage required by turning on the collector junction is, and the more the reduction of the width of the pilot region may be.

According to the bi-mode insulated gate transistor provided by the embodiments of the present invention, the width of the pilot region of the bi-mode insulated gate transistor can be reduced from hundreds of micrometers to dozens of micrometers, thus greatly improving the current uniformity of the chip of the bi-mode insulated gate transistor and improving the reliability of the device. Specifically, the power circulation capability, the capability of resisting current overshoot and the capability of resisting short circuit and the like of the device can be improved.

The layout solution in actual engineering may include various patterns, however, a pilot structure of a small size is formed by isolating part of the P+ collector region according to the structure provided by the embodiments of the present invention. Those solutions through which the width of the P+ collector region of the pilot region can be reduced are not listed one by one in the patent, and all solutions adopting specific technical solutions to reduce the width of the P+ collector region of the pilot region so as to improve the current uniformity are within the protection scope of the patent.

Therefore, the bi-mode insulated gate transistor has the disadvantage that the space between the N+ collector regions on two sides of or surrounding the pilot region is too large, which results in current concentration. The thought of the patent is to reduce the width of the pilot region by virtue of various methods, that is, to reduce the space between the N+ collector regions on two sides of or surrounding the pilot region, thus the current distribution of the pilot region of the bi-mode insulated gate transistor can be further improved and further the reliability of the device is improved.

Finally, it should be noted that the specific embodiments above are merely used for illustrating, rather than limiting the technical solution of the present invention. Although the present invention has been illustrated in detail with reference to examples, it should be understood by those of ordinary skill in the art they can make modifications or equivalent substitutions to the technical of the present invention without departing from the spirit and scope of the technical solution of the present invention, and these modifications or equivalent substitutions should be encompassed in the claims of the present invention.

1. A bi-mode insulated gate transistor, comprising a reverse conducting region and a pilot region;
wherein the reverse conducting region and the pilot region each comprise P+ collector regions, a drift region and a MOS cell region, wherein the drift regions are disposed over the P+ collector regions, and the MOS cell regions are disposed over the drift regions;
the reverse conducting region further comprises N+ collector regions, and the N+ collector regions and the P+ collector regions are alternatively distributed; and
wherein the guide region further comprises a separation region or a low doped region, the separation region isolates the P+ collector regions of the pilot region from the P+ collector regions and the N+ collector regions of the reverse conducting region, and the low doped region is disposed over the P+ collector regions of the pilot region.

2. The bi-mode insulated gate transistor of claim 1, wherein the reverse conducting region and the pilot region each further comprise an N+ buffer layer, the N+ buffer layer of the reverse conducting region is between the P+ collector regions or the N+ collector regions of the reverse conducting region and the drift region of the reverse conducting region, the N+ buffer layer of the pilot region is between the P+ collector regions of the pilot region and the drift region of the pilot region, and the separation region of the pilot region isolates the N+ buffer layer of the reverse conducting region and the N+buffer layer of the pilot region.

3. The bi-mode insulated gate transistor of claim 2, wherein an insulator region is below the separation region, the insulator region is located between a silicon substrate and a collector metal layer, and the width of the insulator region is adjusted to realize potential isolation of the N+ buffer layer of the pilot region and collector metal.

4. The bi-mode insulated gate transistor of claim 1, wherein the separation region is a groove filled with an insulator.

5. The bi-mode insulated gate transistor of claim 2, wherein the concentration of the N+ buffer layer of the pilot region is smaller than that of the N+ buffer layer of the reverse conducting region.

6. The bi-mode insulated gate transistor of claim 2, wherein the concentration of the low doped region is smaller than those of the N+ buffer layer of the pilot region and the P+ collector region of the pilot region.
